(19) United States
(12) Patent Application Publication
(10) Pub. No.: US 2014/0070358 A1
(43) Pub. Date: Mar. 13, 2014

(54) METHOD OF TAILORING SILICON TRENCH PROFILE FOR SUPER STEEP RETROGRADE WELL FIELD EFFECT TRANSISTOR

(71) Applicants: Yi Qi, Fishkill, NY (US); Puneet Khanna, Wappingers Falls, NY (US); Srikanth Samavedam, Fishkill, NY (US); Vara G. Vakada, Beacon, NY (US); Michael P. Ganz, Fishkill, NY (US); Sri Charan Vemula, Fishkill, NY (US); Laegu Kang, Hopewell Junction, NY (US); Bharat V. Krishnan, Clifton Park, NY (US)

(72) Inventors: Yi Qi, Fishkill, NY (US); Puneet Khanna, Wappingers Falls, NY (US); Srikanth Samavedam, Fishkill, NY (US); Vara G. Vakada, Beacon, NY (US); Michael P. Ganz, Fishkill, NY (US); Sri Charan Vemula, Fishkill, NY (US); Laegu Kang, Hopewell Junction, NY (US); Bharat V. Krishnan, Clifton Park, NY (US)

(73) Assignee: GLOBALFOUNDRIES Inc., Grand Cayman (KY)

(21) Appl. No.: 13/612,032

(22) Filed: Sep. 12, 2012

(51) Int. Cl. H01L 29/06; H01L 21/76

(52) U.S. Cl. 257/499; 438/400; 257/E21.54; 257/E29.005

(57) ABSTRACT

A methodology is disclosed enabling the formation of silicon trench profiles for devices, such as SSRW FETs, having a resultant profile that enables desirable epitaxial growth of semiconductor materials. Embodiments include forming a trench in a silicon wafer between STI regions, thermally treating the silicon surfaces of the trench, and forming Si:C in the trench. The process eliminates a need for an isotropic silicon etch to achieve a desirable flat surface. Further, the flat bottom surface provides a desirable surface for epitaxial growth of semiconductor materials, such as Si:C.

### TECHNICAL FIELD

The present disclosure relates to semiconductor devices with epitaxially grown of semiconductor materials. The present disclosure is particularly applicable to Super Steep Retrograde Well (SSRW) Field Effect Transistor (EFT) formation using carbon-doped silicon (Si:C).

### BACKGROUND

The utilization of SSRW designs is known to enhance device performance while suppressing short-channel effects. Various devices employ a step-doping channel profile using Si:C. Si:C is capable of providing an excellent p-type (B/ln) diffusion barrier and forming a steep channel profile for n-channel MOSFETs (Nfets). Conventionally, in forming such devices, a deep trench is created in an Nfet region before a threshold voltage (Vth) adjustment ion implantation. A common procedure for creating such a trench is via reactive ion etching (RIE) using, for example, a dry etch chemistry. Afterwards, the deep Nfet trench is filled with Si:C via epitaxial growth.

FIG. 1 depicts a silicon wafer 101 having a conventional trench 103 formed via RIE for subsequent epitaxial growth of a semiconductor material. The trench 103 is formed between oxide shallow trench isolation (STI) regions 105 that isolate semiconductor devices from each other. The nature of Si:C growth and process integration requirements necessitate the bottom surface of the epitaxial growth region to be flat. However, this limits the RIE process to being anisotropic in nature, as the oxide STI regions 105 that enclose the silicon trench 103 have slanting sidewalls 107. The slanting sidewalls 107, coupled with the anisotropic RIE profile, cause silicon silvers 109 to remain after the RIE.

Adverting to FIG. 2, epitaxial growth of Si:C 203 with silicon slivers 109 is depicted. A sidewall of the silicon sliver 109 that is exposed during epitaxial growth causes the epitaxial growth of the Si:C 203 to proceed in an undesirable fashion as Si:C grows from both the sidewalls and the bottom. The resultant profile is not compatible with the subsequent process flow and can result in inferior electrical performance due to crystalline facets.

Adverting to FIG. 3, a conventionally desirable SSRW Field Effect Transistor (FET) 301, having a flat bottom profile, is depicted. The SSRW FET 301 includes boron-doped silicon 303 and epitaxially grown carbon-doped silicon 305. Obtaining a resultant desirable profile, such as that of FIG. 3, requires an isotropic silicon etch. However, an isotropic etch can result in a bottom profile having a tub shape and/or a rough/contoured surface. Thus, the need for a flat bottom surface precludes the use of a subsequent isotropic etch to form the trench and remove the silicon slivers 109.

A need therefore exists for methodology enabling the formation of silicon trench profiles for devices, such as SSRW FETs, having a resultant profile that enables desirable epitaxial growth of semiconductor materials and the resultant device.

### SUMMARY

An aspect of the present disclosure is an improved method of forming and tailoring a silicon trench profile for a semiconductor device, such as a SSRW.

Another aspect of the present disclosure is a semiconductor device, such as a SSRW, having a silicon trench profile that enables desirable epitaxial growth.

Additional aspects and other features of the present disclosure will be set forth in the description which follows and in part will be apparent to those having ordinary skill in the art upon examination of the following or may be learned from the practice of the present disclosure. The advantages of the present disclosure may be realized and obtained as particularly pointed out in the appended claims.

According to the present disclosure, some technical effects may be achieved in part by a method including: forming a trench in a silicon wafer between shallow trench isolation (STI) regions; thermally treating silicon surfaces of the trench; and forming carbon-doped silicon (Si:C) in the trench.

Aspects of the present disclosure include forming the trench by reaction ion etching (RIE). Further aspects include thermally treating the silicon surfaces of the trench by thermally oxidizing the silicon surfaces. In other aspects, silicon slivers are formed during formation of the trench, and the thermal oxidation of the silicon wafer converts the silicon slivers to silicon dioxide and oxidizes a bottom surface of the silicon wafer. Other aspects include etching oxide formed on the bottom surface of the trench. In additional aspects, thermally treating the silicon surfaces of the trench by hydrogen (H₂) baking the silicon surfaces. In yet other aspects, the shape of the silicon wafer is determined by controlling chamber parameters for the H₂ baking, for example temperature, such as to between 850° and 1000° Celsius, pressure, e.g. to between 2 and 10 Torr, and duration.

Another aspect of the present disclosure includes a device including a silicon substrate; oxide STI regions in the silicon substrate; a thermally treated silicon trench in the substrate between STI regions with no silicon between side surfaces of the trench and the STI regions; and carbon-doped silicon (Si:C) epitaxially grown in the trench.

Aspects include a device including a trench formed by reactive ion etching. Further aspects include a device including a trench thermally treated by thermal oxidization of silicon surfaces of the trench. Another aspect includes a device including a trench thermally treated by hydrogen (H₂) baking An additional aspect includes a shape of the silicon trench being determined by control of temperature, pressure, and duration of the H₂ baking.

Another aspect of the present disclosure is a method including: in-situ hydrogen chlorine (HCl) etching a silicon wafer, forming a trench; smoothing a bottom surface of the trench; and epitaxially growing Si:C in the trench. An additional aspect includes in-situ dry etching or a wet preclean of the silicon wafer prior to HCL etching.

Aspects include smoothing the bottom surface of the trench by H₂ baking the silicon surface of the trench. Further aspects include determining a shape of the trench by controlling a baking temperature, pressure, and duration. Other aspects include epitaxially growing a silicon liner layer on the bottom surface of the trench after H₂ baking Another aspect includes epitaxially growing, a silicon liner layer on the bottom surface of the trench after HCl etching.

Additional aspects and technical effects of the present disclosure will become readily apparent to those skilled in the art from the following detailed description wherein embodiments of the present disclosure are described simply by way of illustration of the best mode contemplated to carry out the present disclosure. As will be realized, the present disclosure is capable of other and different embodiments, and its several details are capable of modifications in various obvious respects, all without departing from the present disclosure. Accordingly, the drawings and description are to be regarded as illustrative in nature, and not as restrictive.

### BRIEF DESCRIPTION OF THE DRAWINGS

The present disclosure is illustrated by way of example, and not by way of limitation, in the figures of the accompanying drawing and in which like reference numerals refer to similar elements and in which:

FIG. 1 schematically illustrates a silicon wafer having a conventional trench profile formed via RIE;

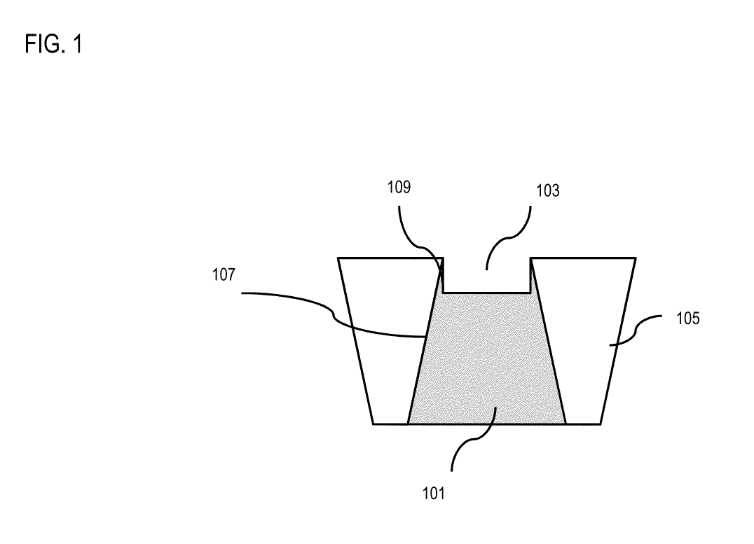

FIG. 2 schematically illustrates projected epitaxial growth with silicon slivers formed on a silicon wafer;

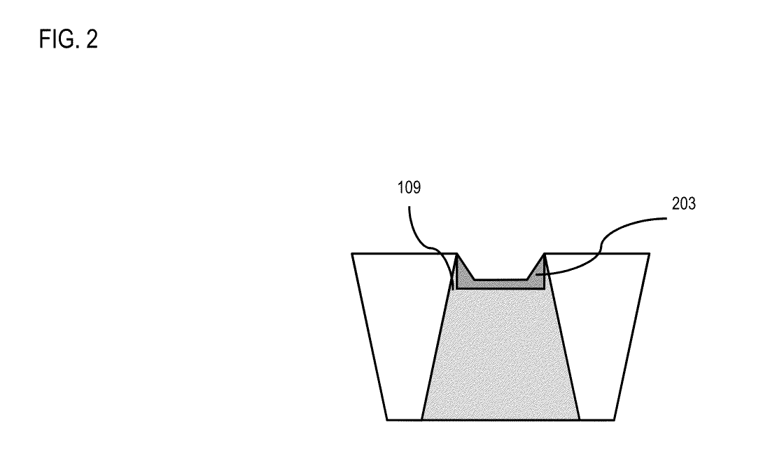

FIG. 3 schematically illustrates a SSRW FET device having a desirable profile;

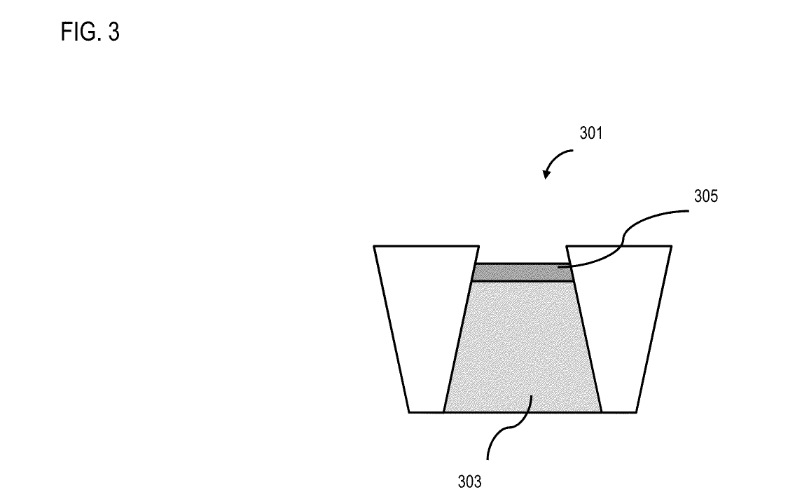

FIG. 4 schematically illustrates a process flow for obtaining desirable epitaxial growth without silicon slivers, in accordance with an exemplary embodiment;

FIG. 5 schematically illustrates a process flow for obtaining desirable epitaxial growth without silicon slivers, in accordance with another exemplary embodiment; and

FIG. 6 schematically illustrates a process flow for obtaining desirable epitaxial growth without silicon slivers, in accordance with another exemplary embodiment.

### DETAILED DESCRIPTION

In the following description, for the purposes of explanation, numerous specific details are set forth in order to provide a thorough understanding of exemplary embodiments. It should be apparent, however, that exemplary embodiments may be practiced without these specific details or with an equivalent arrangement. In other instances, well-known structures and devices are shown in block diagram form in order to avoid unnecessarily obscuring exemplary embodiments. In addition, unless otherwise indicated, all numbers expressing quantities, ratios, and numerical properties of ingredients, reaction conditions, and so forth used in the specification and claims are to be understood as being modified in all instances by the term “about.”

The present disclosure addresses and solves the current problem of silicon sliver growth within a silicon trench profile attendant upon RIE of the trench for epitaxial growth. In accordance with embodiments of the present disclosure, silicon trench profiles are tailored without silicon slivers for epitaxially growing of semiconductor materials. The resultant silicon trench profiles are compatible with subsequent process flows. Therefore, semiconductor materials are epitaxially grown in a desirable fashion.

Embodiments of the present disclosure include forming a trench in a silicon wafer, for example by reactive ion etching. The silicon wafer is thermally treated to remove silicon slivers formed by the RIE. A semiconductor material, such as Si:C, is then formed by epitaxial growth.

Still other aspects, features, and technical effects will be readily apparent to those skilled in this art from the following detailed description, wherein preferred embodiments are shown and described, simply by way of illustration of the best mode contemplated. The disclosure is capable of other and different embodiments, and its several details are capable of modifications in various obvious respects. Accordingly, the drawings and description are to be regarded as illustrative in nature, and not as restrictive.

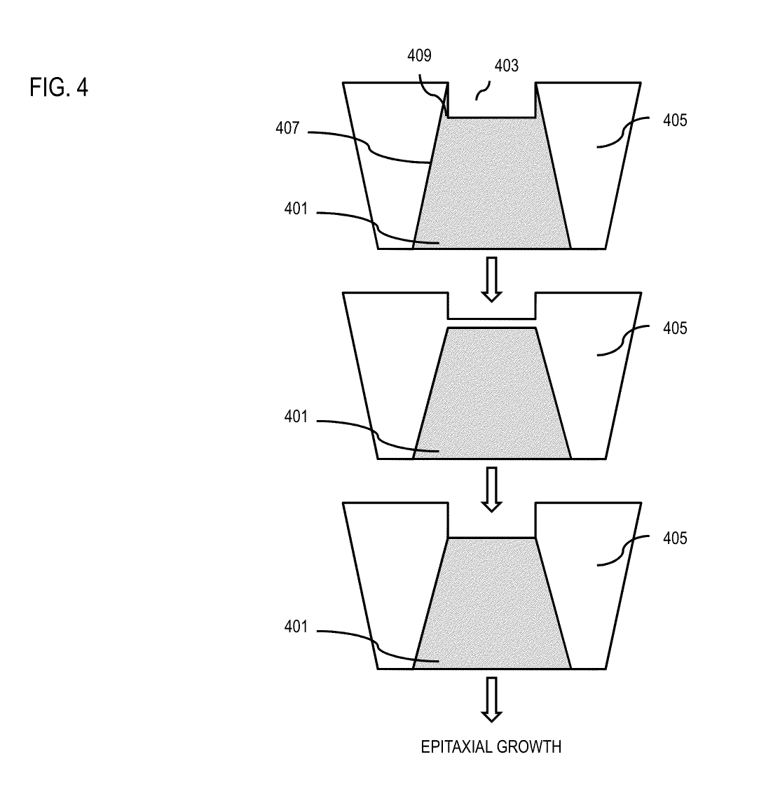

A process flow for fabricating a semiconductor device in accordance with an exemplary embodiment of the present disclosure is depicted in FIG. 4. As illustrated in FIG. 4, a first stage of the process flow illustrates a post RIE profile of a silicon wafer 401 having a conventional trench 403 formed via RIE for subsequent epitaxial growth of a semiconductor material. The trench 403 illustrated in the post RIE profile is formed between oxide STI regions 405 that isolate semiconductor devices from each other. The oxide STI regions 405 that enclose the silicon trench 403 have slanting sidewalls 407. The slanting sidewalls 407, coupled with the anisotropic RIE profile, causes undesirable silicon silvers 409.

FIG. 4 further illustrates a second stage of the flow process that includes a thermal treatment step. The thermal treatment is provided by thermal oxidation. During the thermal oxidation step, the silicon slivers 409 are consumed. As the thermal oxidation step includes a concurrent oxidation of the bottom surface, the thermal oxidation process eliminates any roughness that may be created by the RIE process.

In the third stage of the flow process illustrated in FIG. 4, the newly formed oxide is etched. The oxide etch maybe performed prior to any epitaxial growth. The bottom of the trench 403 can be etched using any silicon dioxide etch, for example, a wet etch using dilute hydrogen fluoride (HF), RIE using trifluoromethane (CHF₃), carbon tetrafluoride (CF₄), or difluoromethane(CH₂F₂), or a dry chemical etch, etc.

Any consequential loss of silicon from the bottom surface of silicon trench 403 or oxide from the top or sides of the oxide STI regions 405 can be factored into the process integration scheme. Furthermore, the flow process depicted in FIG. 4 provides the silicon trench 403 with a flat bottom surface, which eliminates the need for an isotropic silicon etch to achieve a desirable flat surface, which can result in a tub shaped bottom profile or rough/contoured surface. The flat bottom surface provides a desirable surface for epitaxial growth of semiconductor materials, such as Si:C.

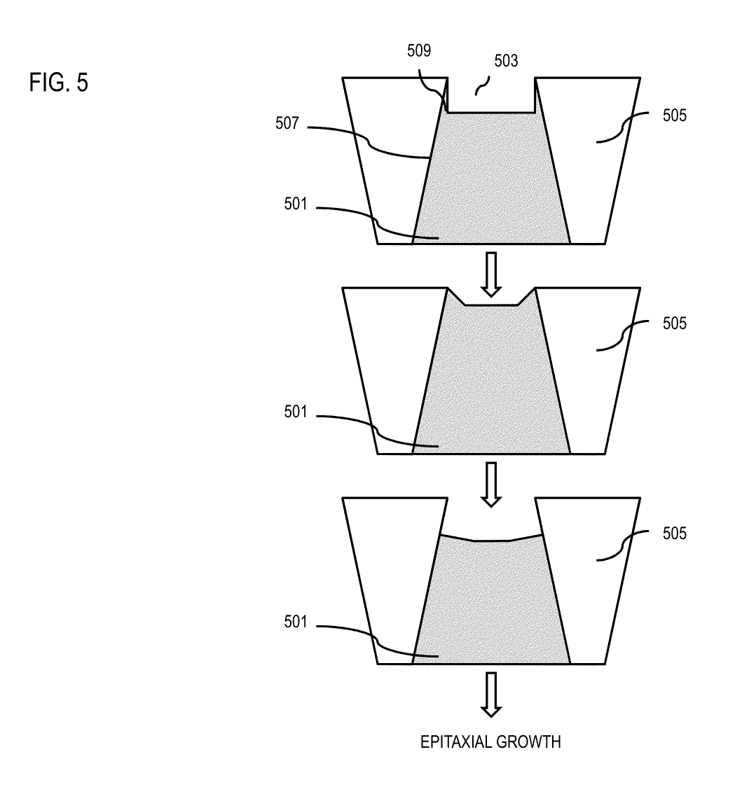

As depicted in FIG. 5, process flow for fabricating a semiconductor device in accordance with another exemplary embodiment of the present disclosure includes three stages. As illustrated in FIG. 5, a first stage of the process flow illustrates a post RIE profile of a silicon wafer 501 having a conventional trench 503 formed via RIE for subsequent epitaxial growth of a semiconductor material. The trench 503 illustrated in the post RIE profile is formed between oxide STI regions 505 similar to trench 403 in FIG. 4. The oxide STI regions 505 that enclose the silicon trench 403 have slanting sidewalls 507. The slanting sidewalls 507, coupled with the anisotropic RIE profile, causes undesirable silicon silvers 509.

FIG. 5 further illustrates a second stage of the flow process that includes a thermal treatment step performed after the RIE and any pre-cleaning steps that may be desired based on particular usage. The thermal treatment step includes thermal rounding with hydrogen (H₂) baking The thermal baking is provided in a high temperature and low pressure in-situ baking epitaxial growth chamber. During the thermal rounding with H₂ baking, Si molecules at the surface migrate due to a thermal rounding effect, or a reduction in surface energy.

As further illustrated in FIG. 5, a third stage of the flow process includes controlling the baking chamber parameters and time, to achieve a desirable flat Si surface of the silicon trench 503. The high temperature baking may be performed from 850° to 1000° celsius and at a low pressure ranging from 2 to 10 Ton. The thermal rounding with H₂ baking can be performed for 20 seconds to 2 minutes. The thermal rounding process eliminates surface roughness created by the RIE process.

In addition, any consequential loss of silicon from the bottom surface of silicon trench 503 or oxide from the top or sides of the oxide STI regions 505 can be factored into the process integration scheme. The flow process depicted in FIG. 5 provides the silicon trench 503 with a flat bottom surface, which eliminates the need for an isotropic silicon etch to achieve a desirable flat surface, which can result in a tub shaped bottom profile of rough/contoured surface. The flat bottom surface provides a desirable surface for epitaxial growth of semiconductor materials, such as Si:C.

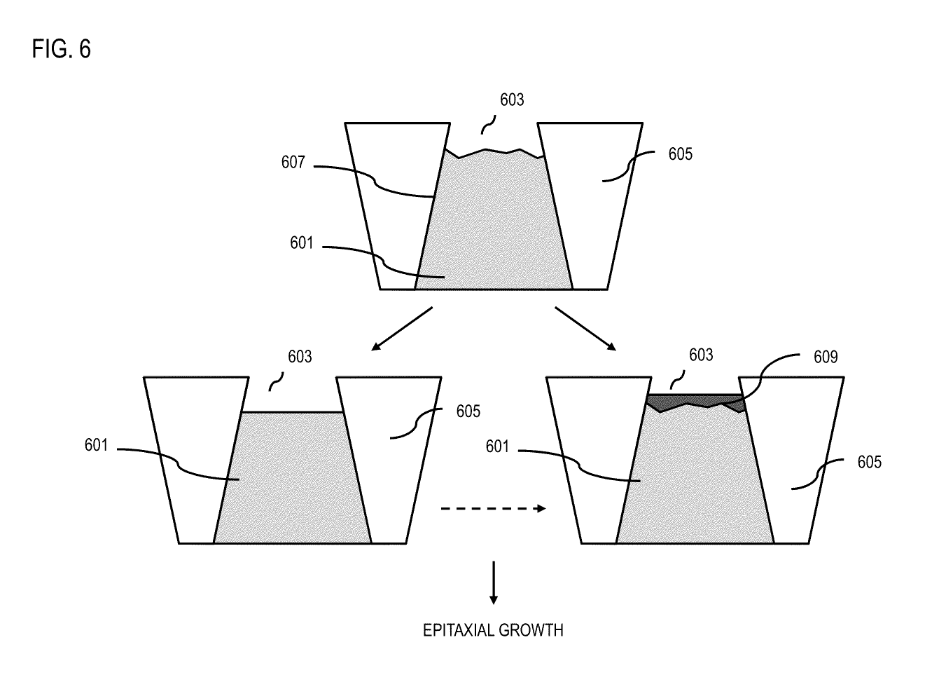

FIG. 6 illustrates a process flow for fabricating a semiconductor device in accordance with an additional exemplary embodiment of the present disclosure. As illustrated in FIG. 6, a first stage of the process flow illustrates a silicon wafer 601 having a conventional trench 603 between STI regions formed via in-situ etching for subsequent epitaxial growth of a semiconductor material. The oxide STI regions 605 that enclose the silicon trench 603 have slanting sidewalls 607. The substrate may be prepared for in-situ etching by a native oxide removal, such as an in-situ dry etch or wet pre-clean. The in-situ etching may then be performed by a hydrogen chloride (HCl) in-situ etch. The nature of the in-situ etching precludes the formation of silicon sidewalls. However, the in-situ etching can result in faceting or contouring of the bottom surface of the silicon trench 605.

FIG. 6 further illustrates a second stage of the flow process. The second stage may include a short H₂ baking step performed after the in-situ etching and any pre-cleaning steps that may be desired based on particular usage. The H₂ baking step can reduce the surface roughness at the bottom of the trench that results from the in-situ etching, due to thermal rounding. The thermal baking is provided at a high temperature and low pressure, without HCl, but in the same chamber as the HCl in situ etch. During the H₂ baking, Si molecules at the surface migrate due to a thermal rounding effect, which is a reduction in surface energy. By controlling the baking chamber parameters and time, a desirable flat Si surface of the silicon trench can be achieved. The thermal rounding with H₂ baking can be performed without HCl for 20 seconds to 2.5 minutes at a high temperature from 850 to 1000 celsius, and at a low pressure ranging from 10 to 20 Torr.

FIG. 6 further illustrates a third stage of the flow process that includes epitaxial growth of a thin silicon liner layer 609. The silicon liner layer 609 is less than 5 nm. The epitaxial growth of the thin silicon liner layer 609 is then followed by epitaxial growth of Si:C or Si. The Si:C epitaxial growth can be 2 to 10 nm, and the Si epitaxial growth can be 5 to 20 nm. As illustrated in FIG. 6, the growth of the thin silicon layer 609 can follow the H₂ bake as a third stage, or replace the H₂ bake of the second stage. Any required implantation or anneal can be implemented after the H₂ bake or the growth of the thin silicon liner layer 609, as needed to accommodate the H₂ bake and compensatory silicon growth.

Although the description has been directed to the formation of methodology enabling the formation of silicon trench profiles for devices, such as SSRW FETs, having a resultant profile that enables desirable epitaxial growth of silicon, the disclosure also applies to various other devices having desirable resultant profiles and that enable epitaxial growth of other semiconductor materials.

The embodiments of the present disclosure can achieve several technical effects, including enablement of the formation of silicon trench profiles for devices, such as SSRW FETs, having a resultant profile that enables desirable epitaxial growth of semiconductor materials. The present disclosure enjoys industrial applicability in fabricating any of various types of highly integrated semiconductor devices, particularly for 20 nm technology products and beyond.

In the preceding description, the present disclosure is described with reference to specifically exemplary embodiments thereof. It will, however, be evident that various modifications and changes may be made thereto without departing from the broader spirit and scope of the present disclosure, as set forth in the claims. The specification and drawings are, accordingly, to be regarded as illustrative and not as restrictive. It is understood that the present disclosure is capable of using various other combinations and embodiments and is capable of any changes or modifications within the scope of the inventive concept as expressed herein.

What is claimed is:

1. A method comprising:
forming a trench in a silicon wafer between shallow trench isolation (STI) regions;
thermally treating silicon surfaces of the trench; and
forming carbon-doped silicon (Si:C) in the trench.

2. The method according to claim 1, comprising forming the trench by reactive ion etching (RIE).

3. The method according to claim 1, comprising thermally treating the silicon surfaces of the trench by thermally oxidizing the silicon surfaces of the trench.

4. The method according to claim 3, wherein silicon slivers are formed during formation of the trench, and the thermal oxidation converts the silicon slivers to silicon dioxide and oxidizes a bottom surface of the silicon wafer.

5. The method according to claim 3, further comprising etching oxide formed on the bottom surface of the trench.

6. The method according to claim 1, comprising thermally treating the silicon surfaces of the trench by hydrogen (H₂) baking the silicon surfaces.

7. The method according to claim 6, further comprising controlling chamber parameters for the H₂ baking.

8. The method according to claim 7, comprising controlling temperature, pressure, and duration for the H₂ baking.

9. The method according to claim 8, comprising controlling the temperature to between 850° and 1000° Celsius and the pressure to between 2 and 10 Ton.

10. A device comprising:
a silicon substrate;
oxide shallow trench isolation (STI) regions in the silicon substrate;
a thermally treated silicon trench in the substrate between STI regions with no silicon between side surfaces of the trench and the STI regions; and
carbon-doped silicon (Si:C) epitaxially grown in the trench.

11. The method according to claim 10 wherein the trench is formed by reactive ion etching.

12. The device according to claim 10, wherein the thermal treatment of the silicon trench includes thermal oxidization of silicon surfaces of the trench.

13. The device according to claim 10, wherein the thermal treatment of the silicon trench includes hydrogen (H₂) baking.

14. The device according to claim 13, wherein the shape of the silicon trench is determined by control of temperature, pressure, and duration of the H₂baking.

15. A method comprising:
in-situ hydrogen chlorine (HCl) etching a silicon wafer, forming a trench;
smoothing a bottom surface of the trench; and
epitaxially growing carbon-doped silicon (Si:C) in the trench.

16. The method according to claim 15, further comprising in-situ dry etching or a wet preclean of the silicon wafer prior to HCL etching.

17. The method according to claim 15, comprising smoothing the bottom surface of the trench by hydrogen (H₂) baking the silicon surface of the trench.

18. The method according to claim 17, comprising determining a shape of the trench by controlling a baking temperature, pressure, and duration.

19. The method according to claim 17, further comprising epitaxially growing a silicon liner layer on the bottom surface of the trench after H₂ baking.

20. The method according to claim 15, further comprising epitaxially growing a silicon liner layer on the bottom surface of the trench after HCl etching.
